(19) United States
(12) Patent Application Publication
(10) Pub. No.: US 2006/0139866 A1
(43) Pub. Date: Jun. 29, 2006

(54) Mounting apparatus of power supply

(75) Inventors: Yun-Lung Chen, Tu-Cheng (TW); Da-Long Sun, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/314,117

(22) Filed: Dec. 20, 2005

(30) Foreign Application Priority Data
Dec. 23, 2004 (CN) 200420103505.2

(51) Int. Cl. G06F 1/16; H05K 7/16

(52) U.S. Cl. 361/683; 361/727

(57) ABSTRACT

A mounting apparatus for a power supply (10) includes a chassis (30) having a rear panel (33) with a plurality of securing slots (39) defined therein, a plurality of securing screws (15) protruding from the power supply (10) and an elastic securing member (20) mounted on the rear panel (33) of the chassis (30). The mounting apparatus further includes a cover (50) attached to the chassis (30). Wherein the securing screw (15) of the power supply (10) is engaged in the securing slots (39) to restrict horizontal movement of the power supply (10), the cover (50) deforms the elastic securing member (20) to restrict vertical movement of the power supply (10).

### BACKGROUND OF THE INVENTION

1. Field of the Invention

The present invention relates to a mounting apparatus, and more particularly to a mounting apparatus for a power supply in a computer chassis.

2. Background of the Invention

Computer systems, such as personal computers and computer servers includes a power supply which is mounted in a housing or chassis along with the other circuits, components, and peripheral devices. Since the power supply receives alternating current electrical power and converts the alternating current to direct current for operating the various electrical components. Safety regulations require that the power supply be completely enclosed in a case to prevent access to potentially harmful high voltages. For example, a conventional computer enclosure has a rear panel forming an opening in an upper portion thereof for mounting a switching power supply therein. Several holes are defined proximate the opening and are aligned with corresponding holes of the power supply for fixing the power supply to the computer enclosure. The power supply is mounted to chassis by a plurality of screws crossing through the holes of the rear panel and the power supply, making it difficult and time consuming to replace or remove the power supply for repair.

Accordingly, what is needed is a mounting apparatus for a power supply easily to be attached and removed from the chassis.

### SUMMARY OF THE INVENTION

A mounting apparatus for a power supply includes a chassis having a rear panel with a plurality of securing slots defined therein, a plurality of securing screws protruding from the power supply and an elastic securing member mounted on the rear panel of the chassis. The mounting apparatus further includes a cover attached to the chassis. The securing screw of the power supply is engaged in the securing slots to restrict horizontal movement of the power supply. The cover deforms the elastic securing member to restrict vertical movement of the power supply.

Other advantages and novel features of the present invention will be drawn from the following detailed description of preferred embodiment with attached drawings, in which:

### BRIEF DESCRIPTION OF THE DRAWINGS

FIG. 1 is an exploded isometric view of the preferred embodiment of a mounting apparatus of a computer power supply;

FIG. 2 is an isometric view of the chassis in FIG. 1, but viewed from another aspect;

FIG. 3 is an assembled view of the mounting apparatus of FIG. 1 with a cover exploded; and

FIG. 4 is an assembled view of the mounting apparatus of FIG. 3.

### DETAIL DESCRIPTION OF THE INVENTION

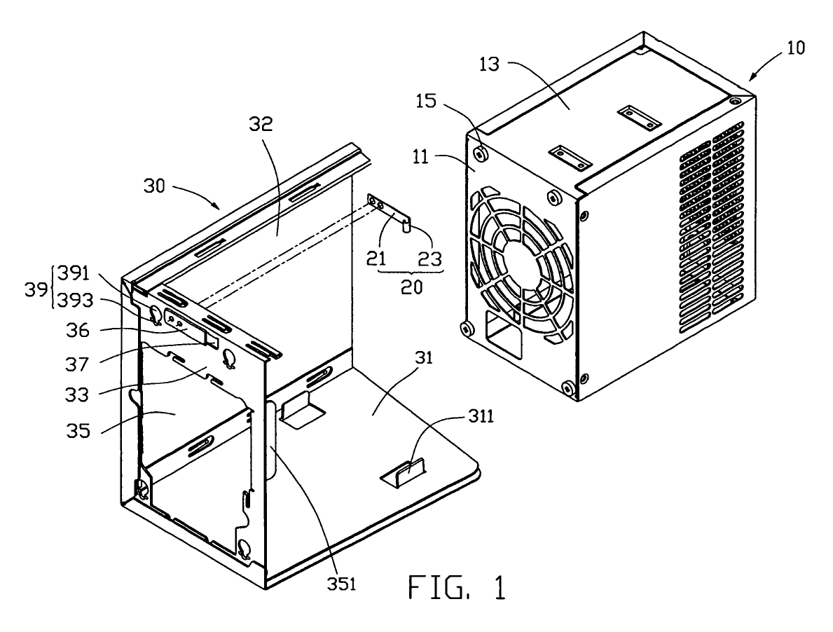

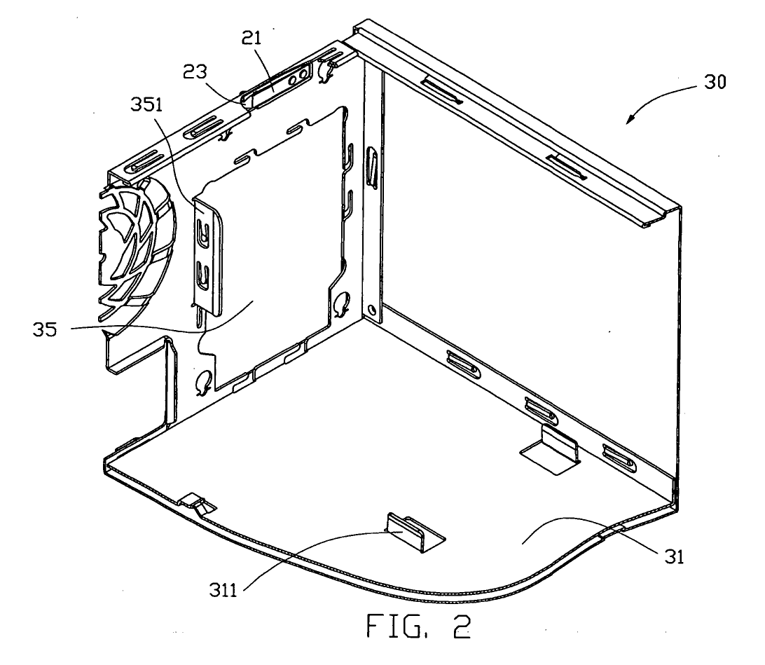

Referring to FIGS. 1 and 2, a mounting apparatus for mounting a power supply 10 in a computer or other electronic devices includes a chassis 30 and an elastic securing member 20. The elastic securing member 20 includes a base portion 21 and a projecting portion 23 extending from the base portion 21, wherein the projecting portion 23 is coil-shaped.

The power supply 10 includes a rear wall 11 with a plurality of securing screws 15 protruding therefrom and a top wall 13. The chassis 30 is formed by a bottom wall 31, a side wall 32 and a rear panel 33. A pair of spaced tabs 311 for limiting the horizontal movement of the power supply 10 is stamped upwardly from the bottom wall 31. An opening 35 is defined in the rear panel 33. A side wall 351 together with the tabs 311 for limiting the horizontal movement of the power supply 10 extends inwardly from one side of the opening 35. The rear panel 33 further includes a plurality of securing slots 39 corresponding to the securing screws 15 of the power supply 10. The securing slot 39 includes a rounded receiving portion 391 for the securing screw 15 protruding through and a U-shaped securing portion 393 for the securing screw 15 engaging to. A receiving portion 36 for receiving the base 21 of the elastic member 20 is stamped outwardly from the rear panel 33 between the upper securing slots 39. A slot 37 for the projecting portion 23 of the elastic securing member 20 protruding through is defined adjacent to the receiving portion 36.

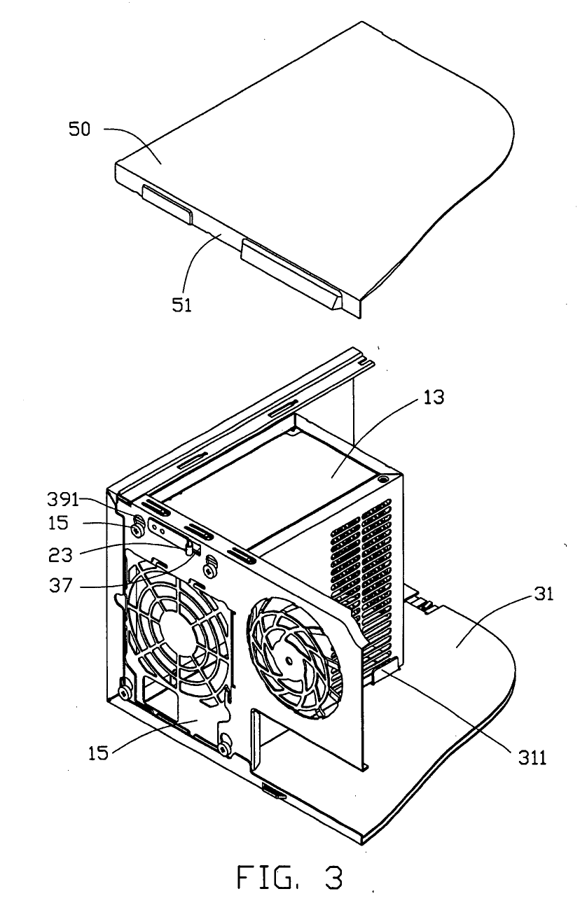

As shown in FIGS. 2 and 3, the elastic securing member 20 is secured to the rear panel 33 of the chassis 30 by rivets or other conventional fastener. In assembly, the power supply 10 is pushed to move toward the rear panel 33 along the tabs 311 until the securing screw 15 protrudes through the receiving hole 391 of the securing slot 39. Then, the power supply 10 is pushed downwardly to force the securing screw 15 to engage in the securing portion 393. The rear wall 11 defines vents for permitting the air to be flowed into or from the components of the power supply 10. The vents of the rear wall 11 is exposed to the opening 35 of the chassis 30. A cover 50 having a flange 51 extending downwardly is pushed forwardly to enclose the power supply 10 in the chassis 30. When the cover 50 is coupled to the chassis 30, the flange 51 of the cover 50 presses the projecting portion 23 of the elastic securing member 20 to retract in the slot 37, thereby blocking the top wall 13 of the power supply 10 from moving upwardly.

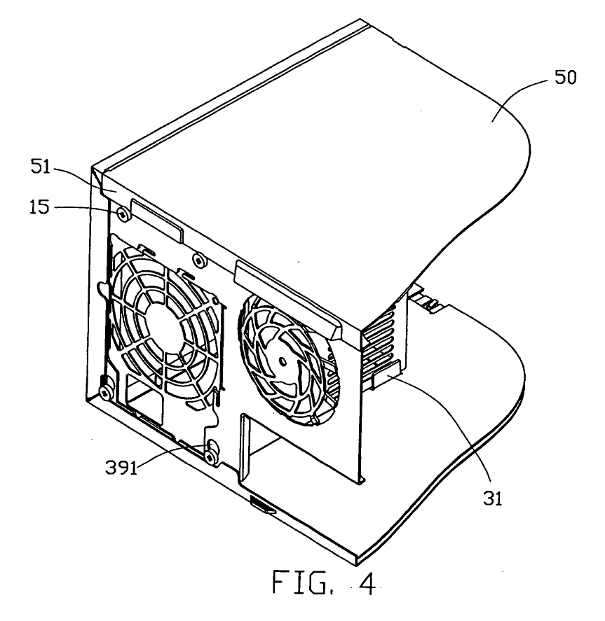

As a result, the side wall 351 and the tabs 311 of the chassis 30 prevent any lateral movement relative to the side wall 32. The securing screw 15 in the securing portion 393 of the securing slot 39 prevents any longitudinal movement relative to the rear panel 33. The projecting portion 23 of the elastic securing member 20 prevents any vertical movement relative to the chassis 30. Thus, the power supply 10 is well secured in its assembled condition relative to the chassis 30 as shown in FIG. 4.

To remove the power supply 10 from the chassis 30 for repair or replacement, the cover 50 is pulled rearwardly to be removed from the chassis 30. The flange 51 of the cover 50 no longer presses against the projecting portion 23 of the elastic securing member 20. The projecting portion 23 rebounds back to initial state and no longer block the top wall 13 of the power supply 10. Then the power supply 10 is moved upwardly to disengage the securing screw 15 from the securing slot 39. So the power supply 10 can be removed from the chassis 30.

It is to be understood, however, that even though numerous characteristics and advantages have been set forth in the foregoing description of preferred embodiments, together with details of the structure and function, the disclosure is illustrative only, and changes may be made in detail, especially in matters of shape, size, and arrangement of parts within the principles of the invention to the full extent indicated by the broad general meaning of the terms in which the appended claims are expressed.

We claim:

1. A mounting apparatus for a power supply comprising:
a chassis having a rear panel with a plurality of securing slots defined therein;
a plurality of securing screws protruding from the power supply;
an elastic securing member mounted on the rear panel of the chassis; and
a cover attached on the chassis, wherein the securing screw of the power supply is engaged in the securing slots to restrict horizontal movement of the power supply, the cover deforms the elastic securing member to restrict vertical movement of the power supply.

2. The mounting apparatus for a power supply as described in claim 1, wherein the chassis comprises a bottom wall with a pair of spaced tabs protruding therefrom.

3. The mounting apparatus for a power supply as described in claim 1, wherein the rear panel of the chassis comprises an opening defined therein, and a side wall for restricting the horizontal movement of the power supply extends from one side of the opening.

4. The mounting apparatus for a power supply as described in claim 1, wherein each securing slot comprises a receiving portion for the securing screw protruding therethrough and a securing portion for the securing screw engaging therein.

5. The mounting apparatus for a power supply as described in claim 1, wherein the elastic securing member comprises a base mounted on the chassis and a projecting portion for restricting the power supply.

6. The mounting apparatus for a power supply as described in claim 5, wherein the projecting portion of the elastic securing member is coil-shaped.

7. The mounting apparatus for a power supply as described in claim 5, wherein a receiving portion for receiving the base of the elastic member is stamped outwardly from the rear panel of the chassis, and a slot for the projecting portion of the elastic member protruding through is defined adjacent to the receiving portion.

8. A mounting apparatus for a power supply comprising:
a chassis with a slot defining therein;
a deformable securing member mounted on the chassis, the securing member comprises a projecting portion; and
a cover mounted on the chassis, the cover pressing against the projecting portion through the slot of the chassis to restrict movement of the power supply.

9. The mounting apparatus for a power supply as described in claim 8, wherein the projecting portion of the deformable securing member is coil-shaped.

10. The mounting apparatus for a power supply as described in claim 8, wherein a plurality of securing pins protrudes from the power supply for engaging to the chassis to restrict a horizontal movement.

11. The mounting apparatus for a power supply as described in claim 10, wherein a plurality of securing slots corresponding to the securing pins is defined in the chassis.

12. The mounting apparatus for a power supply as described in claim 11, wherein each securing slot comprises a receiving portion for the securing pin protruding therethrough and a securing slot for the securing pin engaging therein.

13. The mounting apparatus for a power supply as described in claim 8 wherein the chassis comprises a bottom wall with a pair of spaced tabs protruding therefrom.

14. The mounting apparatus for a power supply as described in claim 8, wherein the chassis defines an opening for exposing the power supply, and a side wall for restricting the horizontal movement of the power supply extends from one side of the opening.

15. An electronic device comprising:
a chassis of said electronic device defining an opening at a side panel thereof;
a power supply capable of movably abutting against said panel of said chassis so as to expose said power supply partially from said opening, said power supply movable along said panel of said chassis between a first position thereof where said power supply is restrained to prevent from moving along a direction away from said panel of said chassis, and a second position thereof where said power supply is released to freely move along said direction; and
a deformable securing member installable at said panel of said chassis beside said first position of said power supply and movable along said direction for said power supply so as to engage with said power supply for retaining said power supply in said first position thereof.

16. The electronic device as described in claim 15, further comprising a cover capable of abutting against said chassis beside said panel of said chassis so as to enclose said electronic device together with said chassis, abutment of said cover against said chassis capable of urging movement of said securing member along said direction to engage with said power supply.
